(19) United States
(12) Patent Application Publication
(10) Pub. No.: US 2026/0231490 A1
(43) Pub. Date: Aug. 6, 2026

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Motoru YOSHIDA, Tokyo (JP); Yutaka FUKUI, Tokyo (JP); Kohei ADACHI, Tokyo (JP); Takaaki TOMINAGA, Tokyo (JP); Akifumi IIJIMA, Tokyo (JP)

(73) Assignee: Mitsubishi Electric Corporation, Tokyo (JP)

(21) Appl. No.: 19/397,501

(22) Filed: Nov. 21, 2025

(30) Foreign Application Priority Data
Jan. 31, 2025 (JP) 2025-014993

(51) Int. Cl. H10D 62/13; H10D 30/01; H10D 30/66; H10D 62/10; H10D 62/832

(52) U.S. Cl. CPC H10D 62/153; H10D 30/0297; H10D 30/668; H10D 62/109; H10D 62/8325

(57) ABSTRACT

A semiconductor device includes a semiconductor layer on which a drift layer is formed, a base layer formed in a surface portion of the semiconductor layer, a source layer and a contact layer formed in a surface portion of the base layer, and a trench that penetrates the source layer and the base layer and reaches the drift layer. An interlayer insulating film covering a gate electrode is embedded in a trench together with a gate insulating film and the gate electrode. The contact layer is thinner than the source layer.

### BACKGROUND

### Technical Field

The present disclosure relates to a trench gate type semiconductor device.

### Description of the Background Art

A trench gate type semiconductor device is known. For example, Japanese Patent Application Laid-Open No. 2013-214660 discloses a trench gate type metal oxide semiconductor field effect transistor (MOSFET) having a structure in which a contact layer connecting to a base region of a source electrode is formed shallower than a base layer.

In a trench gate type semiconductor device, a structure in which an interlayer insulating film covering a gate electrode is embedded in a trench together with a gate electrode has been developed. In the semiconductor device having such a structure, a pitch of cells of a semiconductor element can be shortened, and irregularities on an upper surface of a semiconductor layer can be reduced, so that adhesion between the semiconductor layer and the electrode is improved.

In a case where the interlayer insulating film is embedded in the trench together with the gate electrode, it is necessary to form the trench deeper correspondingly, and depths of a base layer, a source layer, and a contact layer also need to be made deeper accordingly. In particular, the contact layer needs to have a high impurity concentration, and thus, ion implantation for forming the contact layer needs to be performed with high energy. However, ion implantation performed with high energy causes warpage of the semiconductor layer (wafer).

### SUMMARY

An object of the present disclosure is to make it possible to reduce energy of ion implantation for forming a contact layer in a semiconductor device having a structure in which an interlayer insulating film is embedded in a trench together with a gate electrode.

A semiconductor device according to the present disclosure includes: a semiconductor layer including a first main surface and a second main surface opposite to the first main surface and including a drift layer of a first conductivity type formed thereon; a base layer of a second conductivity type formed in a surface portion of the semiconductor layer on a side of the first main surface; a source layer of the first conductivity type formed in a surface portion of the base layer; a trench penetrating the source layer and the base layer and reaching the drift layer; a gate insulating film formed on an inner surface of the trench; a gate electrode formed on the gate insulating film and embedded in the trench; an interlayer insulating film formed on the gate electrode; and a contact layer of the second conductivity type formed in the surface portion of the base layer and having an impurity concentration higher than an impurity concentration of the base layer. The interlayer insulating film is embedded in the trench and does not cover an upper surface of the source layer. The contact layer is thinner than the source layer.

According to the present disclosure, it is possible to reduce energy of ion implantation for forming a contact layer.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a view illustrating a configuration of a semiconductor device according to a first preferred embodiment;

FIG. 2 is a flowchart for describing a method of manufacturing the semiconductor device according to the first preferred embodiment;

FIG. 3 is a view illustrating a configuration of a semiconductor device according to a second preferred embodiment;

FIG. 4 is a view illustrating a configuration of a semiconductor device according to a third preferred embodiment;

FIG. 5 is a view illustrating a configuration of a semiconductor device according to a fourth preferred embodiment;

FIG. 6 is a flowchart for describing a modification of a method of manufacturing the semiconductor device according to the fourth preferred embodiment;

FIG. 7 is a flowchart for describing a modification of a method of manufacturing the semiconductor device according to the fourth preferred embodiment;

FIG. 8 is a view illustrating a configuration of a semiconductor device according to a fifth preferred embodiment;

FIG. 9 is a view illustrating a configuration of a semiconductor device according to a sixth preferred embodiment;

FIG. 10 is a view illustrating a configuration of a semiconductor device according to a seventh preferred embodiment;

FIG. 11 is a flowchart for describing a method of manufacturing the semiconductor device according to the seventh preferred embodiment; and

FIG. 12 is a view illustrating a configuration of a semiconductor device according to an eighth preferred embodiment.

### DESCRIPTION OF THE PREFERRED EMBODIMENTS

In the following preferred embodiments, a first conductivity type is described as an N-type, and a second conductivity type is described as a P-type, but conversely, the first conductivity type may be a P-type, and the second conductivity type may be an N-type. In addition, an N-type having a relatively high impurity concentration is referred to as “N+”, an N-type having a relatively low impurity concentration is referred to as “N−”, a P-type having a relatively high impurity concentration is referred to as “P+”, and a P-type having a relatively low impurity concentration is referred to as “P−”. Here, a level of the impurity concentration of each region is defined by a peak concentration. In other words, a region having a high (or low) impurity concentration means a region having a high (or low) impurity peak concentration.

### First Preferred Embodiment

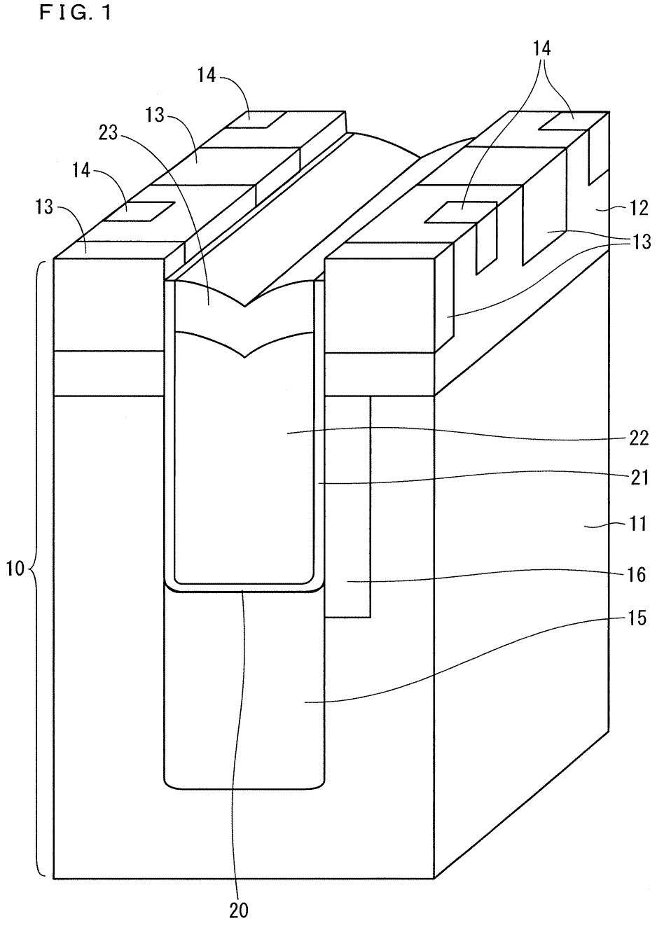

FIG. 1 is a view illustrating a configuration of a semiconductor device according to a first preferred embodiment. Here, description will be provided assuming that a semiconductor element included in the semiconductor device is a MOSFET. However, the semiconductor element only needs to be a trench-type insulated gate semiconductor element, and may be, for example, an element other than a MOSFET such as an insulated gate bipolar transistor (IGBT).

As illustrated in FIG. 1, the semiconductor device according to the first preferred embodiment is formed using a semiconductor layer 10 in which an N-type drift layer 11 is formed. In the present preferred embodiment, the semiconductor layer 10 is made of silicon carbide (SiC). Further, an upper surface of the semiconductor layer 10 illustrated in FIG. 1 is defined as a “first main surface”, and a surface of the semiconductor layer 10 opposite to the first main surface is defined as a “second main surface”. Note that an upper portion of the semiconductor layer 10 is illustrated in FIG. 1, and a second main surface is not illustrated in FIG. 1.

A P-type base layer 12 is formed in a surface portion of the semiconductor layer 10 on a first main surface side. In a surface portion of the base layer 12, an N-type source layer 13 and a P-type contact layer 14 are selectively formed. In the present preferred embodiment, the contact layer 14 has an island shape that is surrounded by the base layer 12 in plan view. An impurity concentration of the contact layer 14 is higher than an impurity concentration of the base layer 12. The contact layer 14 is thinner than the source layer 13, but a region where the contact layer 14 is formed does not overlap with a region where the source layer 13 is formed, and thus, the contact layer 14 is electrically connected to the base layer 12.

A trench 20 that penetrates the source layer 13 and the base layer 12 and reaches the drift layer 11 is formed on the first main surface of the semiconductor layer 10. A gate insulating film 21 is formed on an inner surface of the trench 20. On the gate insulating film 21, a gate electrode 22 is provided so as to be embedded in the trench 20. An interlayer insulating film 23 is formed on the gate electrode 22. The interlayer insulating film 23 is embedded in the trench 20 and does not cover an upper surface of the source layer 13. The source layer 13 needs to have a portion facing the gate electrode 22, and thus, the source layer 13 is formed deep such that a bottom of the source layer 13 is located deeper than a bottom of the interlayer insulating film 23.

Although not illustrated, a source electrode is provided on the semiconductor layer 10 including the trench 20. The source electrode is connected to the source layer 13 and the contact layer 14. In addition, the source electrode is electrically connected to the base layer 12 through the contact layer 14. The source electrode and the gate electrode 22 are insulated by the interlayer insulating film 23.

A P-type electric field relaxation layer 15 is formed on a bottom surface of the trench 20. In addition, a P-type connection layer 16 electrically connecting the electric field relaxation layer 15 and the base layer 12 is formed on one side wall of the trench 20. The connection layer 16 does not need to be continuously formed in an extending direction of the trench 20, and may be locally formed at regular intervals. In a case where the connection layer 16 is locally formed, the connection layer 16 may be provided on both sides of the trench 20. In addition, an N-type well layer having an impurity concentration higher than that of the drift layer 11 may be formed in a portion of the side wall of the trench 20 where the connection layer 16 is not formed in order to lower on-resistance of the MOSFET.

According to the semiconductor device of the first preferred embodiment, the contact layer 14 is thinner than the source layer 13, and thus, the contact layer 14 can be formed by ion implantation with relatively low energy. It is therefore possible to suppress occurrence of warpage in the semiconductor layer 10. In addition, as a result of the region where the contact layer 14 is formed not overlapping with the region where the source layer 13 is formed, it is possible to obtain an effect of suppressing variation in a threshold voltage and the on-resistance of the MOSFET.

In the present preferred embodiment, the semiconductor layer 10 is made of silicon carbide (SiC) known as a wide band gap semiconductor. However, a material of the semiconductor layer 10 may be silicon (Si). In SiC, implanted impurities are less likely to diffuse, and thus, heat treatment at a high temperature is required to sufficiently diffuse the impurities. The heat treatment at a high temperature also causes warpage of the semiconductor layer 10, and thus, an effect of suppressing warpage of the semiconductor layer 10 due to ion implantation is particularly effective in a case where the semiconductor layer 10 is made of SiC.

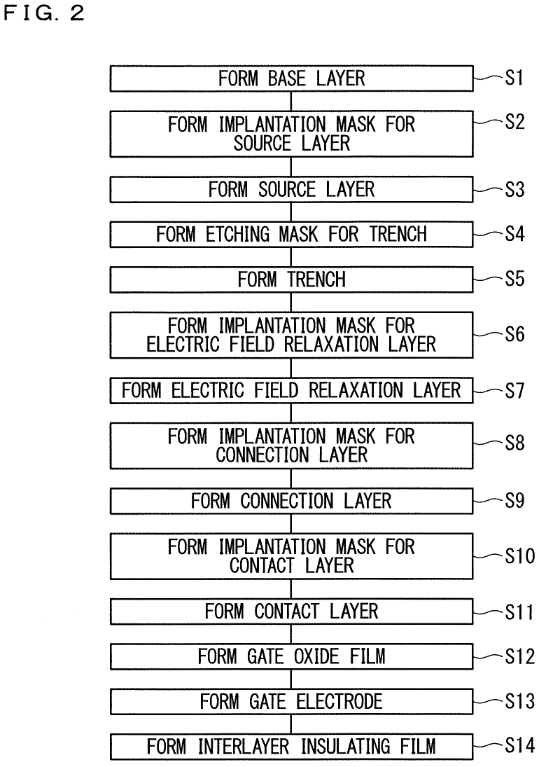

FIG. 2 is a flowchart for describing a method of manufacturing the semiconductor device according to the first preferred embodiment. Hereinafter, the method of manufacturing the semiconductor device according to the first preferred embodiment will be described with reference to FIG. 2.

First, an N-type semiconductor substrate as the semiconductor layer 10 is prepared. Then, impurities are ion-implanted into the entire surface of the first main surface of the semiconductor layer 10 to form the P-type base layer 12 on the surface portion on the first main surface side of the semiconductor layer 10 (step S1).

Next, an implantation mask including a photoresist having an opening in the region where the source layer 13 is to be formed is formed on the first main surface of the semiconductor layer 10 using a photolithography technique (step S2). Then, the N-type source layer 13 is formed in the surface portion of the base layer 12 by ion implantation of impurities using the implantation mask (step S3).

Next, a TEOS oxide film is formed on the first main surface of the semiconductor layer 10, and the TEOS oxide film is patterned using a photolithography technique to form an etching mask having an opening in a region where the trench 20 is to be formed (step S4). Then, by etching using the etching mask, the trench 20 that penetrates the source layer 13 and the base layer 12 and reaches the drift layer 11 is formed on the first main surface of the semiconductor layer 10 (step S5).

Next, a TEOS oxide film is formed on the first main surface of the semiconductor layer 10, and the TEOS oxide film is patterned using a photolithography technique to form an implantation mask having an opening in a region where the electric field relaxation layer 15 is to be formed (step S6). Then, the P-type electric field relaxation layer 15 is formed on the bottom surface of the trench 20 by ion implantation of impurities using the implantation mask (step S7).

Next, a photoresist is formed on the first main surface of the semiconductor layer 10, and the photoresist is patterned using a photolithography technique to form an implantation mask having an opening in a portion of the trench 20 adjacent to the region where the connection layer 16 is to be formed (step S8). Then, the P-type connection layer 16 is formed on the side wall of the trench 20 by ion implantation from an oblique direction using the implantation mask (step S9). In addition, if necessary, an N-type well layer may be formed on the side wall of the trench 20 or a pressure-resistant holding structure such as a P-type guard ring may be formed in a termination region by selective ion implantation by a method similar to steps S8 and S9.

Next, a TEOS oxide film is formed on the first main surface of the semiconductor layer 10, and the TEOS oxide film is patterned using a photolithography technique to form an implantation mask having an opening in a region where the contact layer 14 is to be formed (step S10). In the present preferred embodiment, the region where the contact layer 14 is to be formed does not overlap with the region where the source layer 13 is formed. Then, the P-type contact layer 14 is formed on the surface portion of the base layer 12 by ion implantation of impurities using the implantation mask (step S11). The ion implantation for forming the electric field relaxation layer 15 and the contact layer 14 is performed at a high temperature (for example, 200 degrees), and thus, an implantation mask for the electric field relaxation layer 15 and an implantation mask for the contact layer 14 are formed with a TEOS oxide film instead of a photoresist.

Note that in the semiconductor layer 10, an N-type region where the base layer 12, the source layer 13, the contact layer 14, the electric field relaxation layer 15, and the connection layer 16 are not formed becomes the drift layer 11.

Next, a gate insulating film 21 made of a high temperature silicon oxide (THO) is formed on the inner surface of the trench 20 by chemical vapor deposition (CVD) (step S12).

Next, polysilicon is formed so as to fill the trench 20, and the polysilicon is etched back to form the gate electrode 22 embedded in the trench 20 (step S13).

Thereafter, a TEOS oxide film is formed on the first main surface of the semiconductor layer 10 so as to cover the gate electrode 22, and the TEOS oxide film outside the trench 20 (TEOS oxide film on the first main surface) is removed by etching to form the interlayer insulating film 23 embedded in the trench 20 (step S14).

Through the above steps, the semiconductor device having the configuration illustrated in FIG. 1 is completed.

Note that in the process of etching the TEOS oxide film that forms the implantation mask for the contact layer 14 (step S10), the surface of the semiconductor layer 10 in the region where the contact layer 14 is formed is etched by several tens of nanometers (specifically, 5 nm or more and 100 nm or less) by over-etching. Thus, in the semiconductor device according to the present preferred embodiment, an upper surface of the contact layer 14 is recessed at a depth of 5 nm or more and 100 nm or less.

In addition, the region where the contact layer 14 is formed does not overlap with the region where the source layer 13 is formed, and thus, in a case where the contact layer 14 is formed by one time of ion implantation in the process of forming the contact layer 14 (step S11), the peak of the impurity concentration of the contact layer 14 is only one place in the depth direction of the semiconductor layer 10.

### Second Preferred Embodiment

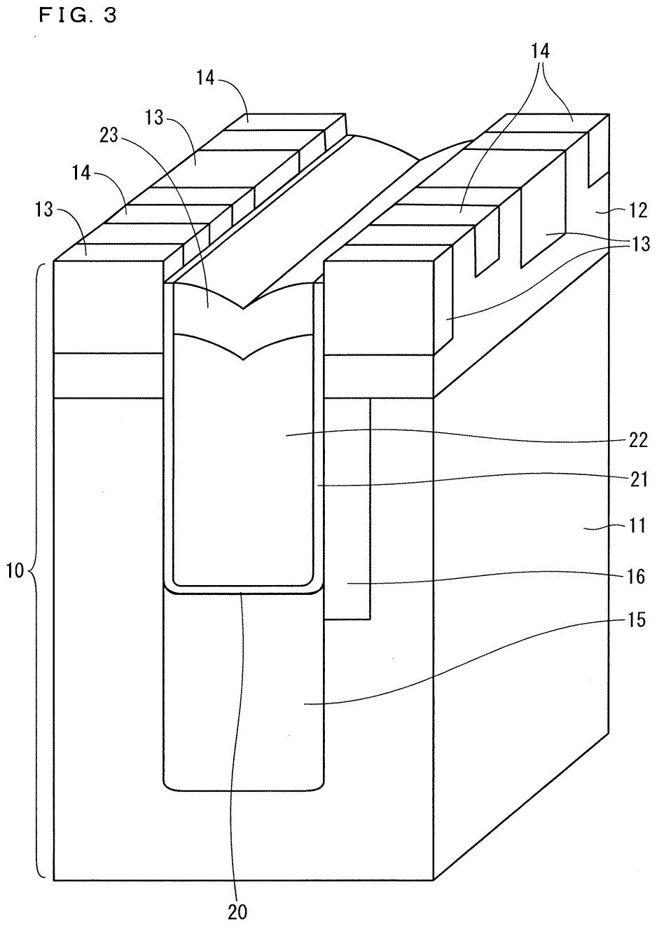

FIG. 3 is a view illustrating a configuration of a semiconductor device according to a second preferred embodiment. The configuration of the semiconductor device according to the second preferred embodiment is different from the configuration of the first preferred embodiment (FIG. 1) in that the contact layer 14 has a stripe shape that is sandwiched between the base layer 12 on both sides and intersects the trench 20 in plan view. Other configurations are similar to those of the first preferred embodiment, and thus, description thereof is omitted.

According to the semiconductor device of the second preferred embodiment, an area of the contact layer 14 can be increased as compared with the first preferred embodiment, and thus, connection resistance between the contact layer 14 and the source electrode can be reduced.

The semiconductor device according to the second preferred embodiment can be formed by a method similar to the manufacturing method (FIG. 2) described in the first preferred embodiment.

### Third Preferred Embodiment

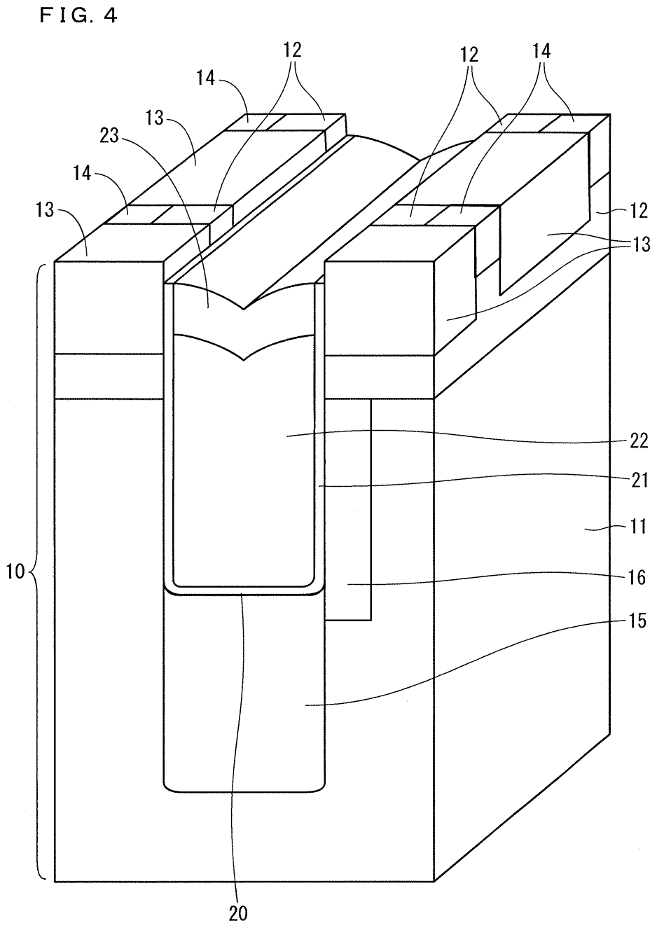

FIG. 4 is a view illustrating a configuration of a semiconductor device according to a third preferred embodiment. The configuration of the semiconductor device according to the third preferred embodiment is different from the configuration of the first preferred embodiment (FIG. 1) in that the contact layer 14 has an island shape that is sandwiched between the source layer 13 in an extending direction of the trench 20 and sandwiched between the base layer 12 in a direction perpendicular to the extending direction of the trench 20 in plan view. Other configurations are similar to those of the first preferred embodiment, and thus, description thereof is omitted.

According to the semiconductor device of the third preferred embodiment, the area of the source layer 13 can be increased as compared with the first preferred embodiment, and thus, the on-resistance of the MOSFET can be reduced.

The semiconductor device according to the third preferred embodiment can be formed by a method similar to the manufacturing method (FIG. 2) described in the first preferred embodiment.

### Fourth Preferred Embodiment

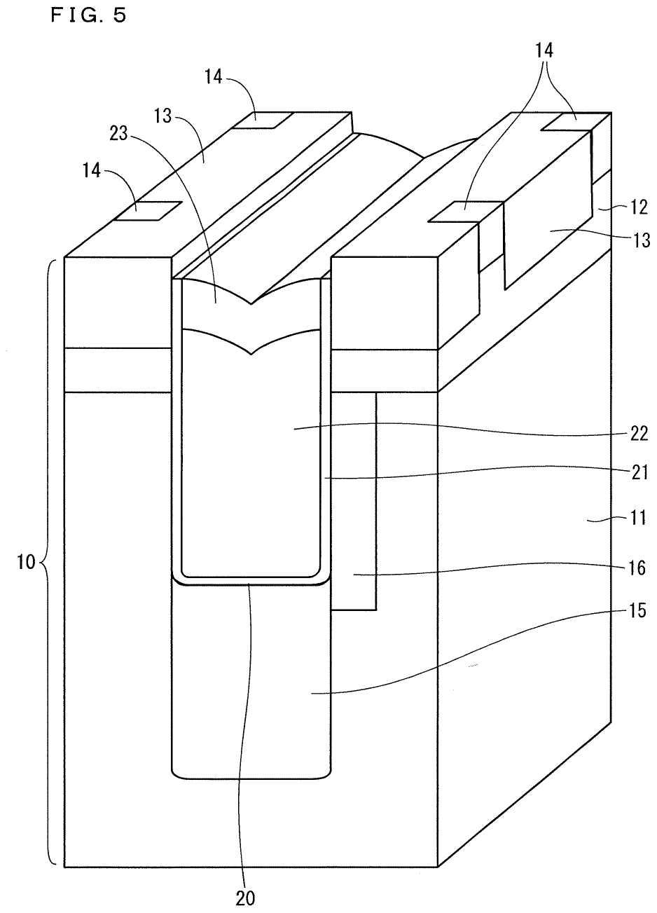

FIG. 5 is a view illustrating a configuration of a semiconductor device according to a fourth preferred embodiment. The configuration of the semiconductor device according to the fourth preferred embodiment is different from the configuration of the first preferred embodiment (FIG. 1) in that the contact layer 14 has an island shape that is surrounded by the source layer 13 in plan view. Other configurations are similar to those of the first preferred embodiment, and thus, description thereof is omitted.

According to the semiconductor device of the fourth preferred embodiment, the area of the source layer 13 can be made further larger than that of the third preferred embodiment, and thus, the on-resistance of the MOSFET can be reduced.

The semiconductor device according to the fourth preferred embodiment can be formed by a method similar to the manufacturing method (FIG. 2) described in the first preferred embodiment.

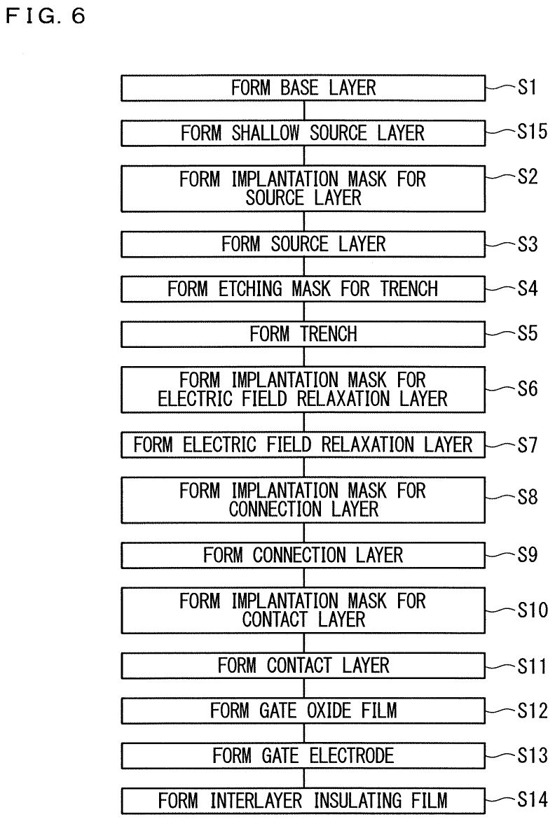

In addition, as in the flowchart of FIG. 6, the source layer 13 may be formed by two ion implantation processes including a process (step S15) of forming the source layer 13 shallower than the contact layer 14 on the entire surface by ion implantation to the entire surface of the semiconductor layer 10 and a process (step S4) of selectively forming the source layer 13 deeper than the contact layer 14 by ion implantation using an implantation mask. This can prevent a gap from being formed between the source layer 13 and the contact layer 14 even if positional displacement occurs between the implantation mask for the source layer 13 and the implantation mask for the contact layer 14.

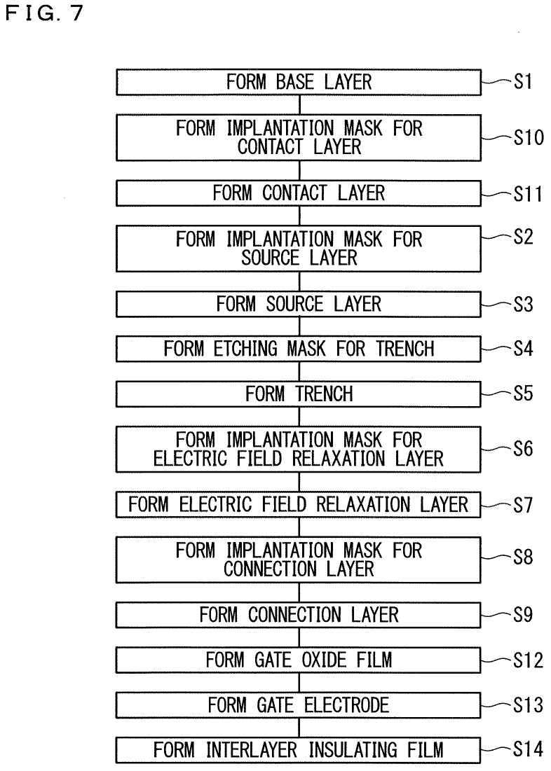

Furthermore, in order to prevent the positional displacement between the implantation mask for the source layer 13 and the implantation mask for the contact layer 14, the source layer 13 can be formed by a self-alignment process. Specifically, as in the flowchart of FIG. 7, prior to the formation of the source layer 13, an implantation mask for the contact layer 14 having an opening in the region where the contact layer 14 is to be formed is formed (step S10), and the contact layer 14 is formed by ion implantation using the implantation mask (step S11). Subsequently, polysilicon is deposited so as to cover the implantation mask for the contact layer 14, and the polysilicon is etched back to form a polysilicon film embedded in the opening of the implantation mask for the contact layer 14. Thereafter, when the implantation mask for the contact layer 14 is removed with hydrofluoric acid (HF), a polysilicon film remains on the region where the contact layer 14 is to be formed, and the polysilicon film is used as an implantation mask for the source layer 13 (step S2). Then, the N-type source layer 13 thicker than the contact layer 14 is formed in the surface portion of the base layer 12 by ion implantation using the implantation mask (step S3). According to this method, the positional displacement between the implantation mask for the source layer 13 and the implantation mask for the contact layer 14 is prevented, and a gap is prevented from being formed between the source layer 13 and the contact layer 14.

### Fifth Preferred Embodiment

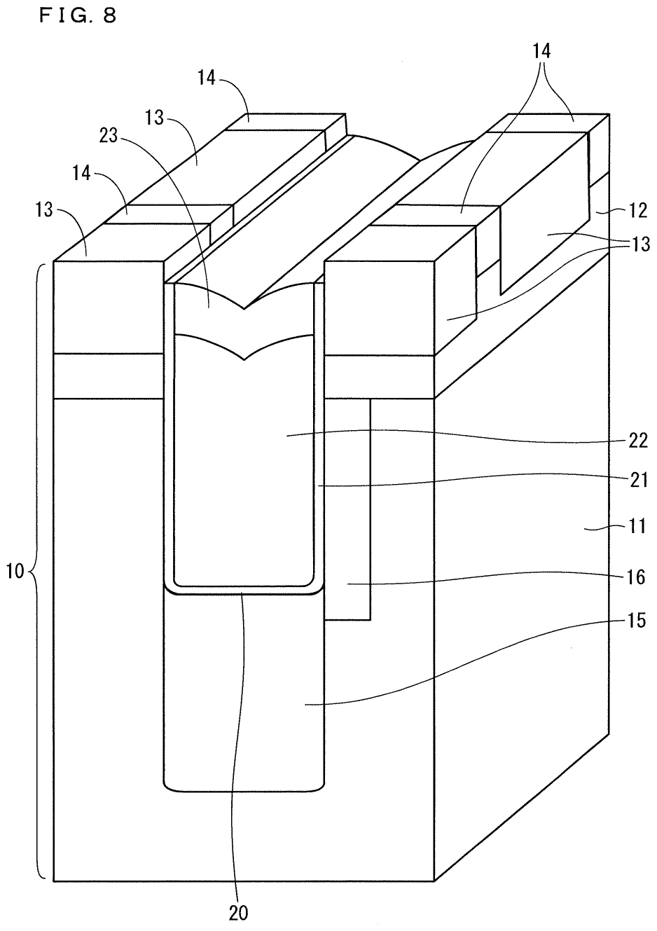

FIG. 8 is a view illustrating a configuration of a semiconductor device according to a fifth preferred embodiment. The configuration of the semiconductor device according to the fifth preferred embodiment is different from the configuration of the first preferred embodiment (FIG. 1) in that the contact layer 14 has a stripe shape that is sandwiched between the source layer 13 on both sides and intersects the trench 20 in plan view. Other configurations are similar to those of the first preferred embodiment, and thus, description thereof is omitted.

According to the semiconductor device of the fifth preferred embodiment, the area of the contact layer 14 can be increased as compared with the fourth preferred embodiment, and thus, the on-resistance of the MOSFET can be reduced while reducing the connection resistance between the contact layer 14 and the source electrode.

The semiconductor device according to the fifth preferred embodiment can be formed by a method similar to the manufacturing method described in the first preferred embodiment (FIG. 2) or the modification of the manufacturing method described in the fourth preferred embodiment (FIG. 6 or 7).

### Sixth Preferred Embodiment

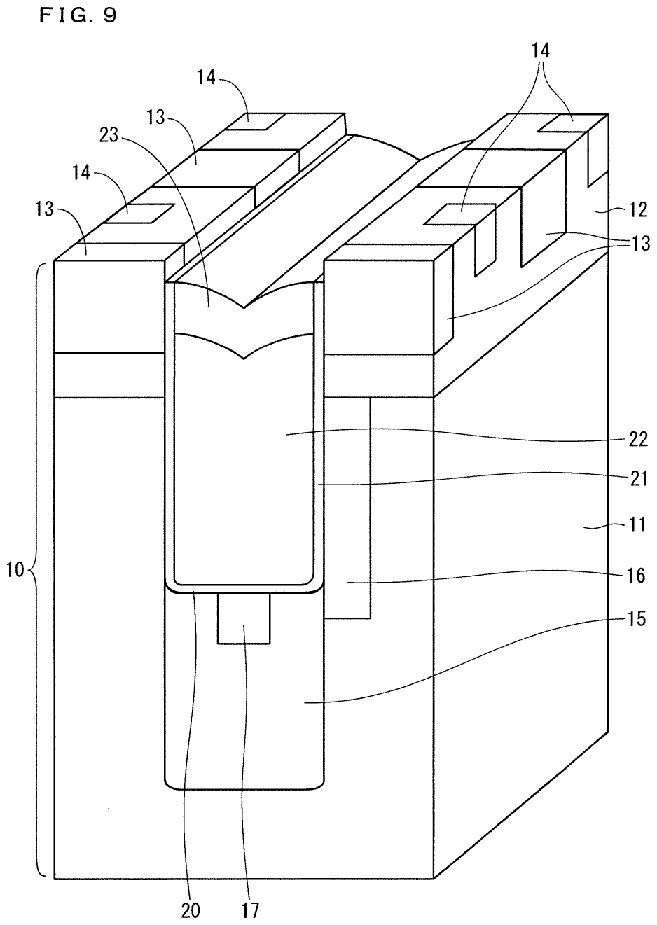

FIG. 9 is a view illustrating a configuration of a semiconductor device according to a sixth preferred embodiment. The configuration of the semiconductor device according to the sixth preferred embodiment is different from the configuration of the first preferred embodiment (FIG. 1) in that a low-resistance layer 17 formed in the electric field relaxation layer 15 on the bottom surface of the trench 20 is provided. The low-resistance layer 17 is formed in the surface portion of the electric field relaxation layer 15 (near the bottom surface of the trench 20), and an impurity concentration profile in the depth direction of the semiconductor layer 10 in the low-resistance layer 17 is the same as an impurity concentration profile in the depth direction of the semiconductor layer 10 in the contact layer 14. Other configurations are similar to those of the first preferred embodiment, and thus, description thereof is omitted. Note that the low-resistance layer 17 is also applicable to preferred embodiments other than the first preferred embodiment.

According to the semiconductor device of the sixth preferred embodiment, the substantial impurity concentration of the electric field relaxation layer 15 is higher than that of the first preferred embodiment, and thus, a function of the electric field relaxation layer 15 that relaxes the electric field in the vicinity of the bottom surface of the trench 20 is improved.

The semiconductor device according to the sixth preferred embodiment can be formed by a method similar to the manufacturing method described in the first preferred embodiment (FIG. 2) or the modification of the manufacturing method described in the fourth preferred embodiment (FIG. 6 or 7). However, in the process of forming an implantation mask for the contact layer 14 (step S10), instead of the trench 20 being completely filled with the TEOS oxide film, a film thickness of the TEOS oxide film is reduced to such an extent that a void (cavity) is formed at the center of the trench 20. By performing the ion implantation process (step S11) of forming the contact layer 14 in this state, the low-resistance layer 17 can be formed simultaneously with the contact layer 14. As a result of simultaneously forming the contact layer 14 and the low-resistance layer 17 in this manner, the contact layer 14 and the low-resistance layer 17 have the same impurity concentration profiles in the depth direction of the semiconductor layer 10.

### Seventh Preferred Embodiment

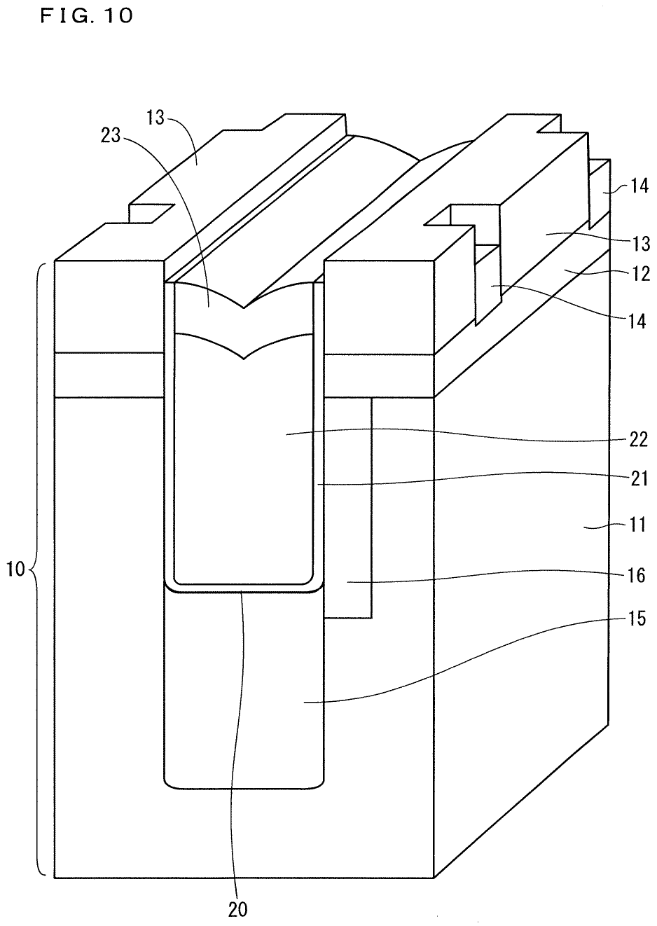

FIG. 10 is a view illustrating a configuration of a semiconductor device according to a seventh preferred embodiment. The configuration of the semiconductor device according to the seventh preferred embodiment is different from the configuration of the fourth preferred embodiment (FIG. 5) in that a recess is provided on the upper surface of the contact layer 14. A depth of the recess is such that the bottom of the contact layer 14 thinner than the source layer 13 is located deeper than the bottom of the source layer 13. Similarly to FIG. 5, the contact layer 14 has an island shape that is surrounded by the source layer 13 in plan view. Other configurations are similar to those of the first preferred embodiment, and thus, description thereof is omitted.

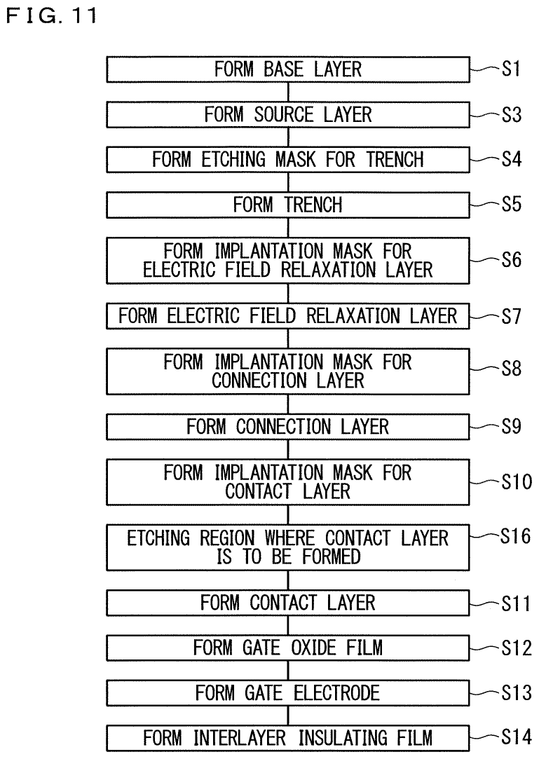

FIG. 11 is a flowchart for describing a method of manufacturing the semiconductor device according to the seventh preferred embodiment. The flowchart of FIG. 11 is obtained by omitting the process (step S2) of forming the implantation mask for the source layer 13 and adding the process (step S16) of etching the region where the contact layer 14 is to be formed after the process (step S10) of forming the implantation mask for the contact layer 14 to the flowchart of FIG. 2 described in the first preferred embodiment.

Step S2 is omitted, and thus, in step S3, impurities are ion-implanted to the entire first main surface of the semiconductor layer 10, and the source layer 13 is formed on the entire first main surface of the semiconductor layer 10.

In step S16, the first main surface of the semiconductor layer 10 is etched using the implantation mask for the contact layer 14 formed in step S10 as an etching mask. As a result, a recess is formed in a portion of the upper surface of the region where the contact layer 14 is to be formed. By performing ion implantation for forming the contact layer 14 in the region where the recess is formed (step S11) in this state, the contact layer 14 reaching the base layer 12 under the source layer 13 can be formed by ion implantation with relatively low energy. In other words, even if the thin contact layer 14 is formed by relatively low-energy ion implantation, the bottom of the contact layer 14 can be located deeper than the bottom of the source layer 13.

According to the semiconductor device of the seventh preferred embodiment, similarly to the first preferred embodiment, the contact layer 14 can be formed by ion implantation with relatively low energy, so that it is possible to suppress occurrence of warpage in the semiconductor layer 10. In addition, similarly to the fourth preferred embodiment, the area of the source layer 13 can be increased, and thus, the on-resistance of the MOSFET can be reduced.

### Eighth Preferred Embodiment

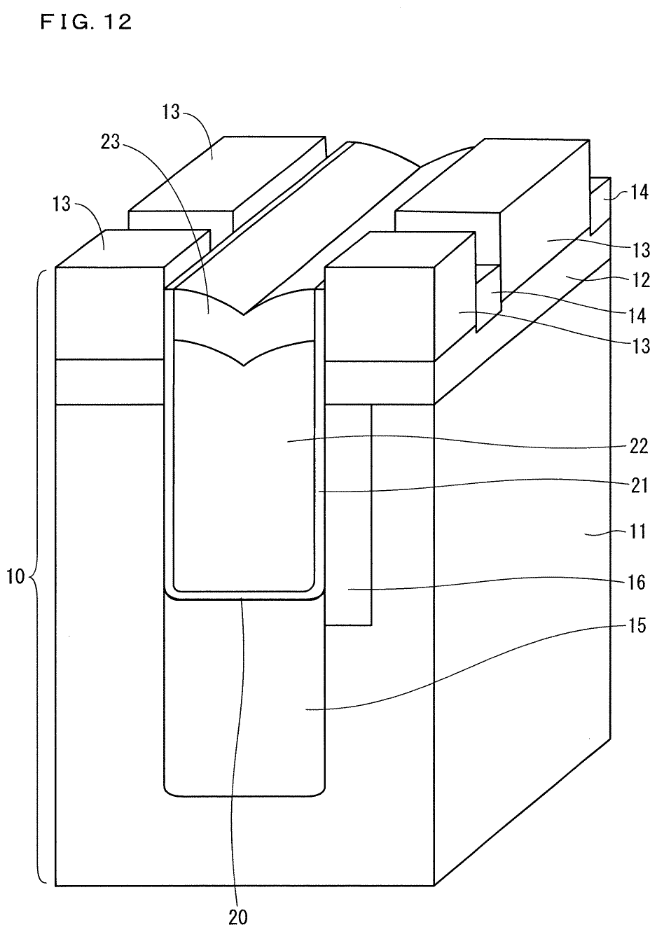

In an eighth preferred embodiment, an example in which the seventh preferred embodiment is applied to the fifth preferred embodiment will be described. FIG. 12 is a view illustrating a configuration of a semiconductor device according to the eighth preferred embodiment. The configuration of the semiconductor device according to the eighth preferred embodiment is different from the configuration of the fifth preferred embodiment (FIG. 8) in that a recess is provided on the upper surface of the contact layer 14. A depth of the recess is such that the bottom of the contact layer 14 thinner than the source layer 13 is located deeper than the bottom of the source layer 13. Similarly to FIG. 8, the contact layer 14 has a stripe shape that is sandwiched between the source layers 13 on both sides and intersects the trench 20 in plan view. Other configurations are similar to those of the first preferred embodiment, and thus, description thereof is omitted.

The semiconductor device according to the eighth preferred embodiment can be formed by the manufacturing method (FIG. 11) described in the seventh preferred embodiment.

Also in the semiconductor device according to the eighth preferred embodiment, similarly to the seventh preferred embodiment, the contact layer 14 can be formed by ion implantation with relatively low energy, so that it is possible to suppress occurrence of warpage in the semiconductor layer 10. In addition, the area of the contact layer 14 can be increased as compared with the seventh preferred embodiment, and thus, the on-resistance of the MOSFET can be reduced while reducing the connection resistance between the contact layer 14 and the source electrode.

Note that the preferred embodiments can be freely combined, and the preferred embodiments can be appropriately modified or omitted.

### Appendix

Hereinafter, various aspects of the present disclosure will be collectively described as appendixes.

### Appendix 1

A semiconductor device comprising:
a semiconductor layer including a first main surface and a second main surface opposite to the first main surface and including a drift layer of a first conductivity type formed thereon;
a base layer of a second conductivity type formed in a surface portion of the semiconductor layer on a side of the first main surface;
a source layer of the first conductivity type formed in a surface portion of the base layer;
a trench penetrating the source layer and the base layer and reaching the drift layer;
a gate insulating film formed on an inner surface of the trench;
a gate electrode formed on the gate insulating film and embedded in the trench;
an interlayer insulating film formed on the gate electrode, embedded in the trench, and not covering an upper surface of the source layer; and
a contact layer of the second conductivity type formed in the surface portion of the base layer, thinner than the source layer, and having an impurity concentration higher than an impurity concentration of the base layer.

### Appendix 2

The semiconductor device according to Appendix 1, wherein the contact layer has an island shape that is surrounded by the base layer in plan view.

### Appendix 3

The semiconductor device according to Appendix 1, wherein the contact layer has a stripe shape that is sandwiched between the base layer on both sides and intersects the trench in plan view.

### Appendix 4

The semiconductor device according to Appendix 1, wherein the contact layer has an island shape that is sandwiched between the source layer in an extending direction of the trench and sandwiched between the base layer in a direction perpendicular to the extending direction of the trench in plan view.

### Appendix 5

The semiconductor device according to Appendix 1, wherein the contact layer has an island shape that is surrounded by the source layer in plan view.

### Appendix 6

The semiconductor device according to Appendix 1, wherein the contact layer has a stripe shape that is sandwiched between the source layer on both sides and intersects the trench in plan view.

### Appendix 7

The semiconductor device according to Appendix 1, wherein
an upper surface of the contact layer is recessed on the first main surface of the semiconductor layer, and
a bottom of the contact layer is located deeper than a bottom of the source layer.

### Appendix 8

The semiconductor device according to Appendix 7, wherein the contact layer has an island shape that is surrounded by the source layer in plan view.

### Appendix 9

The semiconductor device according to Appendix 7, wherein the contact layer has a stripe shape that is sandwiched between the source layer on both sides and intersects the trench in plan view.

### Appendix 10

The semiconductor device according to any one of Appendixes 1 to 6, wherein an upper surface of the contact layer is recessed on the first main surface of the semiconductor layer by a depth of 5 nm or more and 100 nm or less.

### Appendix 11

The semiconductor device according to any one of Appendixes 1 to 6, wherein a peak of an impurity concentration of the contact layer is only one place in a depth direction of the semiconductor layer.

### Appendix 12

The semiconductor device according to any one of Appendixes 1 to 11, wherein a bottom of the source layer is located deeper than a bottom of the insulating film.

### Appendix 13

The semiconductor device according to any one of Appendixes 1 to 12, further comprising:
an electric field relaxation layer of the second conductivity type formed on a bottom surface of the trench; and
a low-resistance layer formed in the electric field relaxation layer on a bottom surface of the trench, the low-resistance layer having an impurity concentration profile in a depth direction of the semiconductor layer the same as an impurity concentration profile of the contact layer.

### Appendix 14

The semiconductor device according to any one of Appendixes 1 to 13, wherein the semiconductor layer is made of silicon carbide.

### Appendix 15

A method of manufacturing a semiconductor device, the method comprising:
a step of preparing a semiconductor layer including a first main surface and a second main surface opposite to the first main surface and including a drift layer of a first conductivity type formed thereon;
a step of forming a base layer by ion-implanting an impurity of a second conductivity type into a surface portion of the semiconductor layer on a side of the first main surface;
a step of forming a source layer by ion-implanting an impurity of the first conductivity type into a surface portion of the base layer; and
a step of forming a contact layer having an impurity concentration higher than an impurity concentration of the base layer and thinner than the source layer by ion-implanting an impurity of the second conductivity type into the surface portion of the base layer,
wherein
a region where the base layer is formed does not overlap with a region where the contact layer is formed.

### Appendix 16

A method of manufacturing a semiconductor device, the method comprising:
a step of preparing a semiconductor layer including a first main surface and a second main surface opposite to the first main surface and including a drift layer of a first conductivity type formed thereon;
a step of forming a base layer by ion-implanting an impurity of a second conductivity type into a surface portion of the semiconductor layer on a side of the first main surface;
a step of forming a contact layer having an impurity concentration higher than an impurity concentration of the base layer in a surface portion of the base layer by ion-implanting an impurity of the second conductivity type using a first mask having an opening in the base layer;

a step of forming a second mask on a region where the contact layer is to be formed by embedding the second mask in the opening of the first mask and removing the first mask; and
a step of forming a source layer thicker than the contact layer by ion-implanting an impurity of the first conductivity type into the surface portion of the base layer using the second mask.

### Appendix 17

A method of manufacturing a semiconductor device, the method comprising:
a step of preparing a semiconductor layer including a first main surface and a second main surface opposite to the first main surface and including a drift layer of a first conductivity type formed thereon;
a step of forming a base layer by ion-implanting an impurity of a second conductivity type into a surface portion of the semiconductor layer on a side of the first main surface;
a step of forming a source layer by ion-implanting an impurity of the first conductivity type into a surface portion of the base layer;
a step of forming a recess in a portion of an upper surface of the source layer; and
a step of forming a contact layer having an impurity concentration higher than an impurity concentration of the base layer and thinner than the source layer by ion-implanting an impurity of the second conductivity type into a region where the recess is formed.

While the disclosure has been shown and described in detail, the foregoing description is in all aspects illustrative and not restrictive. It is therefore understood that numerous modifications and variations can be devised.

What is claimed is:

1. A semiconductor device, comprising:
a semiconductor layer including a first main surface and a second main surface opposite to the first main surface and including a drift layer of a first conductivity type formed thereon;
a base layer of a second conductivity type formed in a surface portion of the semiconductor layer on a side of the first main surface;
a source layer of the first conductivity type formed in a surface portion of the base layer;
a trench penetrating the source layer and the base layer and reaching the drift layer;
a gate insulating film formed on an inner surface of the trench;
a gate electrode formed on the gate insulating film and embedded in the trench;
an interlayer insulating film formed on the gate electrode, embedded in the trench, and not covering an upper surface of the source layer; and
a contact layer of the second conductivity type formed in the surface portion of the base layer, thinner than the source layer, and having an impurity concentration higher than an impurity concentration of the base layer.

2. The semiconductor device according to claim 1, wherein the contact layer has an island shape that is surrounded by the base layer in plan view.

3. The semiconductor device according to claim 1, wherein the contact layer has a stripe shape that is sandwiched between the base layer on both sides and intersects the trench in plan view.

4. The semiconductor device according to claim 1, wherein the contact layer has an island shape that is sandwiched between the source layer in an extending direction of the trench and sandwiched between the base layer in a direction perpendicular to the extending direction of the trench in plan view.

5. The semiconductor device according to claim 1, wherein the contact layer has an island shape that is surrounded by the source layer in plan view.

6. The semiconductor device according to claim 1, wherein the contact layer has a stripe shape that is sandwiched between the source layer on both sides and intersects the trench in plan view.

7. The semiconductor device according to claim 1, wherein
an upper surface of the contact layer is recessed on the first main surface of the semiconductor layer, and
a bottom of the contact layer is located deeper than a bottom of the source layer.

8. The semiconductor device according to claim 7, wherein the contact layer has an island shape that is surrounded by the source layer in plan view.

9. The semiconductor device according to claim 7, wherein the contact layer has a stripe shape that is sandwiched between the source layer on both sides and intersects the trench in plan view.

10. The semiconductor device according to claim 1, wherein an upper surface of the contact layer is recessed on the first main surface of the semiconductor layer by a depth of 5 nm or more and 100 nm or less.

11. The semiconductor device according to claim 1, wherein a peak of an impurity concentration of the contact layer is only one place in a depth direction of the semiconductor layer.

12. The semiconductor device according to claim 1, wherein a bottom of the source layer is located deeper than a bottom of the insulating film.

13. The semiconductor device according to claim 1, further comprising:
an electric field relaxation layer of the second conductivity type formed on a bottom surface of the trench; and
a low-resistance layer formed in the electric field relaxation layer on a bottom surface of the trench, the low-resistance layer having an impurity concentration profile in a depth direction of the semiconductor layer the same as an impurity concentration profile of the contact layer.

14. The semiconductor device according to claim 1, wherein the semiconductor layer is made of silicon carbide.

15. A method of manufacturing a semiconductor device, the method comprising:
preparing a semiconductor layer including a first main surface and a second main surface opposite to the first main surface and including a drift layer of a first conductivity type formed thereon;
forming a base layer by ion-implanting an impurity of a second conductivity type into a surface portion of the semiconductor layer on a side of the first main surface;
forming a source layer by ion-implanting an impurity of the first conductivity type into a surface portion of the base layer; and
forming a contact layer having an impurity concentration higher than an impurity concentration of the base layer and thinner than the source layer by ion-implanting an impurity of the second conductivity type into the surface portion of the base layer,
wherein a region where the base layer is formed does not overlap with a region where the contact layer is formed.

16. A method of manufacturing a semiconductor device, the method comprising:
preparing a semiconductor layer including a first main surface and a second main surface opposite to the first main surface and including a drift layer of a first conductivity type formed thereon;
forming a base layer by ion-implanting an impurity of a second conductivity type into a surface portion of the semiconductor layer on a side of the first main surface;
forming a contact layer having an impurity concentration higher than an impurity concentration of the base layer in a surface portion of the base layer by ion-implanting an impurity of the second conductivity type using a first mask having an opening in the base layer;
forming a second mask on a region where the contact layer is to be formed by embedding the second mask in the opening of the first mask and removing the first mask; and
forming a source layer thicker than the contact layer by ion-implanting an impurity of the first conductivity type into the surface portion of the base layer using the second mask.

17. A method of manufacturing a semiconductor device, the method comprising:
preparing a semiconductor layer including a first main surface and a second main surface opposite to the first main surface and including a drift layer of a first conductivity type formed thereon;
forming a base layer by ion-implanting an impurity of a second conductivity type into a surface portion of the semiconductor layer on a side of the first main surface;
forming a source layer by ion-implanting an impurity of the first conductivity type into a surface portion of the base layer;
forming a recess in a portion of an upper surface of the source layer; and
forming a contact layer having an impurity concentration higher than an impurity concentration of the base layer and thinner than the source layer by ion-implanting an impurity of the second conductivity type into a region where the recess is formed.
